(19) United States
(12) Patent Application Publication
(10) Pub. No.: US 2025/0081569 A1
(43) Pub. Date: Mar. 6, 2025

(54) METAL TREATMENT ON METAL SILICIDE FOR CMOS DEVICES

(71) Applicant: Applied Materials, Inc., Santa Clara, CA (US)

(72) Inventors: Nicolas Louis BREIL, San Jose, CA (US); Avgerinos V. GELATOS, Scotts Valley, CA (US)

(21) Appl. No.: 18/817,419

(22) Filed: Aug. 28, 2024

Related U.S. Application Data
(60) Provisional application No. 63/536,294, filed on Sep. 1, 2023.

(51) Int. Cl. H01L 29/40; H01L 21/768; H01L 29/49

(52) U.S. Cl. CPC H10D 64/01; H01L 21/76846; H01L 21/76877; H01L 21/76897; H10D 64/667

(57) ABSTRACT

A method of forming an electrical contact in a semiconductor structure includes performing a cavity shaping process on a semiconductor structure having a p-type semiconductor region for a p-type metal oxide semiconductor (p-MOS) device, the cavity shaping process comprising forming a first cavity in an exposed surface of the p-type semiconductor region, performing a first selective deposition process to form a first cavity contact, selectively in the first cavity, and performing a metal treatment process on the formed first cavity contact, to remove oxides at interfaces of the first cavity contact with the first cavity.

### CROSS-REFERENCE TO RELATED APPLICATIONS

This application claims priority to U.S. Provisional Application Ser. No. 63/536,294 filed Sep. 1, 2023, which is herein incorporated by reference in its entirety.

### BACKGROUND

### Field

Embodiments described herein generally relate to semiconductor device fabrication, and more particularly, to systems and methods of forming an electrical contact within a semiconductor structure.

### Description of the Related Art

Multi-gate metal-oxide-semiconductor field-effect transistors (MOSFETs), such as complementary metal-oxide semiconductor (CMOS) devices, pose challenges in manufacturability due to their three-dimensional (3D) designs and small sizes. In advanced CMOS devices, metal silicide (e.g. molybdenum silicide (MoSi₂), ruthenium silicide (RuₓSi_{y})) selectively formed at a bottom of a trench contact is often utilized to lower a contact resistivity. However, interfaces of metal silicide at the bottom of a trench contact in a p-type MOS (p-MOS) region often suffer from low structural and electrical qualities.

Therefore, there is a need for methods and systems that can improve structural and electrical qualities of the interfaces of metal silicide at a bottom of a trench contact.

### SUMMARY

Embodiments of the present disclosure provide a method of forming an electrical contact in a semiconductor structure. The method includes performing a cavity shaping process on a semiconductor structure having a p-type semiconductor region for a p-type metal oxide semiconductor (p-MOS) device, the cavity shaping process comprising forming a first cavity in an exposed surface of the p-type semiconductor region, performing a first selective deposition process to form a first cavity contact, selectively in the first cavity, and performing a metal treatment process on the formed first cavity contact, to remove oxides at interfaces of the first cavity contact with the first cavity.

Embodiments of the present disclosure also provide a method of forming an electrical contact in a semiconductor structure. The method includes performing a pre-clean process on a semiconductor structure having an n-type semiconductor region for an n-type metal oxide semiconductor (n-MOS) device, and a p-type semiconductor region for a p-type metal oxide semiconductor (p-MOS) device, and a dielectric layer having a first trench over the n-type semiconductor region and a second trench over the p-type semiconductor region, performing a cavity shaping process to form a second cavity in an exposed surface of the n-type semiconductor region within the first trench and a first cavity in an exposed surface of the p-type semiconductor region within the second trench, performing a first selective deposition process to form a first cavity contact, selectively in the first cavity, performing a metal treatment process on the formed first cavity contact, to remove oxides at interfaces of the first cavity contact with the first cavity, performing a second selective deposition process to form a second cavity contact, selectively in the second cavity, performing a blanket deposition process to form a barrier layer on exposed inner surfaces of the first trench and the second trench and on the exposed surface of the dielectric layer, and performing a metal fill process to form a first contact plug in the first trench and a second contact plug in the second trench.

Embodiments of the present disclosure further provide a processing system. The processing system includes a first processing chamber, a second processing chamber, a third processing chamber, and a system controller configured to cause the processing system to perform, in the first processing chamber, a cavity shaping process on a semiconductor structure having an n-type semiconductor region for an n-type metal oxide semiconductor (n-MOS) device and a p-type semiconductor region for a p-type metal oxide semiconductor (p-MOS) device, the cavity shaping process comprising forming a second cavity in an exposed surface of the n-type semiconductor region and a first cavity in an exposed surface of the p-type semiconductor region, perform, in the second processing chamber, a first selective deposition process to form a first cavity contact, selectively in the first cavity, and perform, in the third processing chamber, a metal treatment process on the formed first cavity contact, to remove oxides at interfaces of the first cavity contact with the first cavity, wherein the metal treatment process includes a capacitively coupled plasma (CCP) chemical etch process with ion bombardment using processing gas including hydrogen (H₂) and argon (Ar).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of a multi-chamber processing system according to one or more embodiments of the present disclosure.

FIG. 2 depicts a process flow diagram of a method of forming a contact layer in a semiconductor structure according to one or more embodiments of the present disclosure.

FIGS. 3A, 3B, 3C, 3D, 3E, and 3F are cross-sectional views of a portion of a semiconductor structure corresponding to various states of the method of FIG. 2.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide methods and systems for forming an electrical contact that includes metal silicide (e.g. molybdenum silicide (MoSi₂), ruthenium silicide (RuₓSi_{y})) at a selected portion (e.g., on an exposed surface of a layer of silicon germanium) of a structure that is used to form a CMOS device, and further improving structural and electrical qualities of the metal silicide at interfaces. The methods and systems may be particularly useful for forming, in a semiconductor structure having a region that includes silicon, a region that includes silicon germanium, a dielectric layer formed thereover, and a metal silicide contact (e.g. molybdenum silicide (MoSi₂), ruthenium silicide (RuₓSi_{y})) formed selectively on an exposed surface of the silicon germanium material within an opening or feature (e.g., contact trench) in the dielectric layer. The processes described herein are configured to form cavities in the opening or feature (e.g., contact trench), surfaces of which are optimized for selective deposition of metal silicide, and remove oxides at interfaces of the metal silicide contact with the cavities.

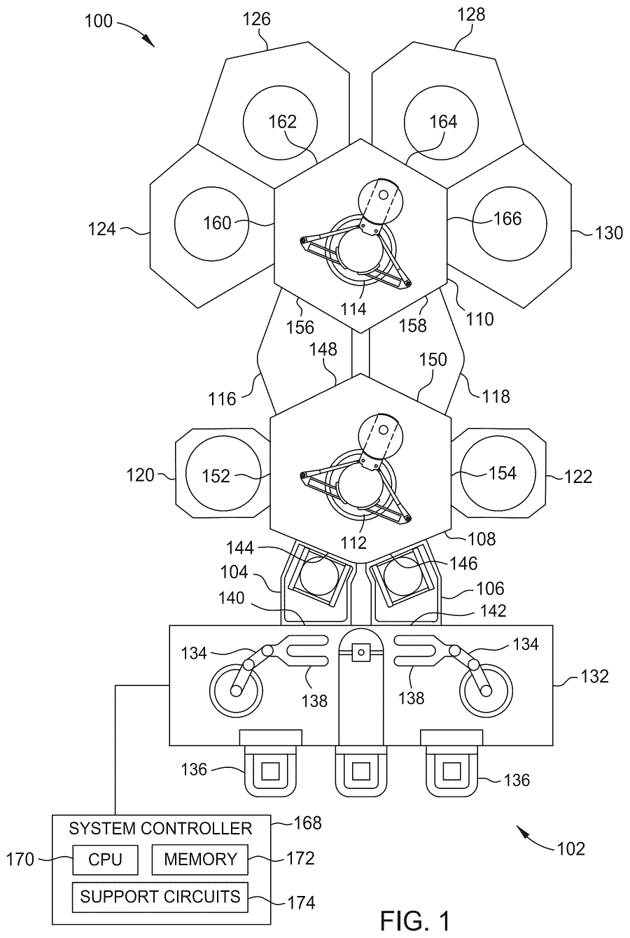

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

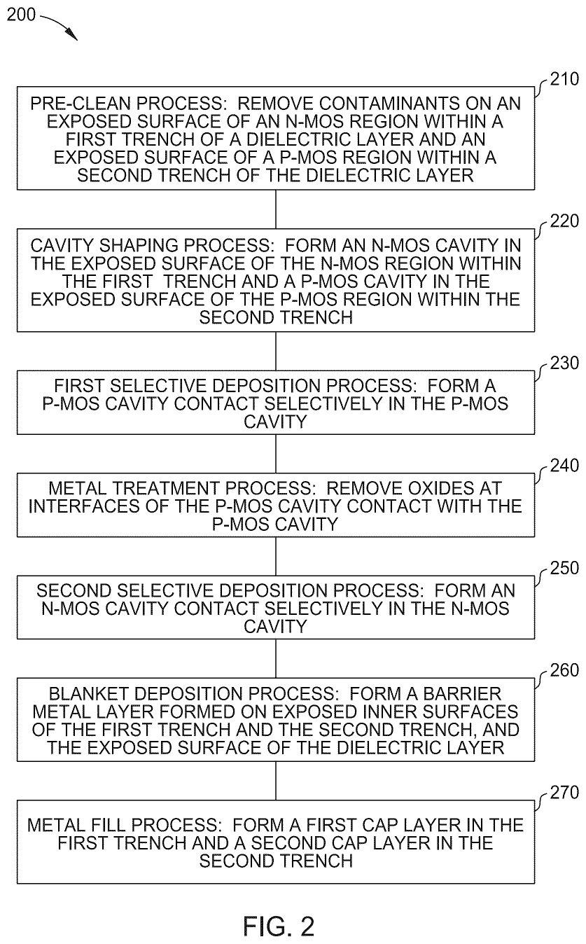

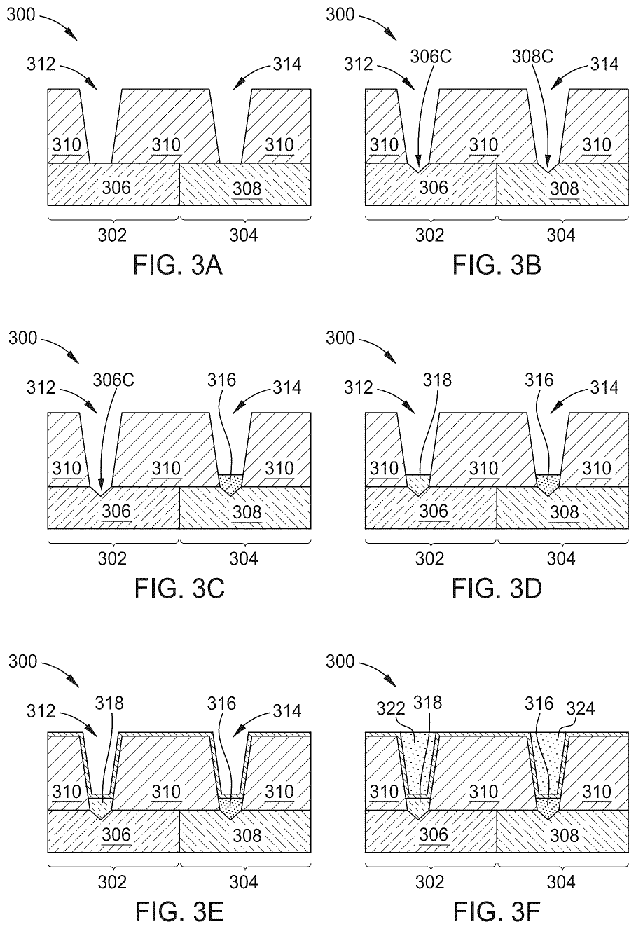

FIG. 2 depicts a process flow diagram of a method 200 of forming a contact layer in a semiconductor structure 300 according to some embodiments of the present disclosure. FIGS. 3A, 3B, 3C, 3D, 3E, and 3F are cross-sectional views of a portion of the semiconductor structure 300 corresponding to various states of the method 200. It should be understood that FIGS. 3A, 3B, 3C, 3D, 3E, and 3F illustrate only partial schematic views of the semiconductor structure 300, and the semiconductor structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

Referring to FIGS. 3A, 3B, 3C, 3D, 3E, and 3F, the semiconductor structure 300 may include an n-type MOS device 302 and a p-type MOS device 304 formed on a substrate (not shown).

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

As shown in FIG. 3A, a portion of an n-type MOS device 302 of a plurality of n-type transistor devices formed on the substrate includes an n-type semiconductor region 306 formed of a first material, such as silicon (Si). A portion of a p-type MOS device 304 of a plurality of p-type transistor devices formed on the substrate includes a p-type semiconductor region 308 formed of a second material, such as silicon germanium (SiGe). The first and second materials include materials having differing compositions, such that the second material can be selectively etched relative to the first material (i.e., an etch rate of the second material is higher than an etch rate of the first material). The etch selectivity of the second material (i.e., a ratio of the etch rate of the second material to the etch rate of the first material) is between about 10:1 to 500:1. Other example combinations of the first material and the second material include silicon (Si)/silicon germanium (SiGe), germanium (Ge)/silicon germanium (SiGe), or silicon (Si)/germanium tin (GeSn), respectively.

The n-type semiconductor regions 306 may be doped with n-type dopants such as phosphorus (P), antimony (Sb), with the concentration between about 10²⁰ cm⁻³ and 5·x 10²¹ cm⁻³, depending upon the desired conductive characteristic of the n-type MOS device 302. The p-type semiconductor regions 308 may be doped with p-type dopants such as boron (B) or gallium (Ga), with the concentration of between about 10²⁰ cm⁻³ and about 5·x 10²¹ cm⁻³, depending upon the desired conductive characteristic of the p-type MOS device 304.

The semiconductor structure 300 further includes a dielectric layer 310 having a first trench 312 formed over the n-type semiconductor region 306 and a second trench 314 formed over the p-type semiconductor region 308. The dielectric layer 310 may be formed of a dielectric material, such as silicon dioxide (SiO₂) or silicon nitride (Si₃N₄).

The n-type semiconductor region 306 and the p-type semiconductor region 308 may be formed using any suitable deposition technique, such as epitaxial (Epi) deposition, chemical vapor deposition (CVD), atomic layer deposition (ALD), or physical vapor deposition (PVD), and the first and second trenches 312 and 314 are formed by a patterning technique, such as a lithography and etch process.

The method 200 begins with a pre-clean process in block 210. The pre-clean process may be performed in a processing chamber, such as the processing chamber 122 shown in FIG. 1. The pre-clean process in block 210 may be performed without breaking vacuum environment in a multi-chamber processing system, such as the multi-chamber processing system 100 shown in FIG. 1.

The pre-clean process is configured to remove contaminants, such as carbon-containing contaminants (e.g., patterning residues), or oxide-containing contaminants (e.g., native oxide layers) formed on the exposed surface of the n-type semiconductor region 306 within the first trench 312 and the exposed surface of the p-type semiconductor region 308 within the second trench 314.

The pre-clean process to remove carbon-containing contaminants may include an anisotropic remote plasma assisted dry etch process, such as a reactive ion etching (RIE) process, using a plasma formed from a gas including hydrogen (H), argon (Ar), helium (He), or a combination thereof. The plasma effluents directionally bombard and remove a remaining dielectric layer within the first trench 312 and the second trench 314.

The pre-clean process to remove oxide-containing contaminants may include an isotropic plasma etch process, such as a dry chemical etch process, using hydrofluoric acid (HF) and ammonia (NH₃), or a SiCoNi™ dry etch process, using a plasma formed from a gas including ammonia (NH₃), nitrogen trifluoride (NF₃). The dry etch process is selective for oxide layers, and thus does not readily etch silicon, germanium, or nitride layers regardless of whether the layers are amorphous, crystalline or polycrystalline. Selectivity of the dry etch process for oxide versus silicon or germanium is at least about 3:1, and usually 5:1 or better, sometimes 10:1. The dry etch process is also highly selective of oxide versus nitride. The selectivity of the dry etch process versus nitride is at least about 3:1, usually 5:1 or better, sometimes 10:1.

In block 220, a cavity shaping process is performed to form an n-MOS cavity 306C in the exposed surface of the n-type semiconductor region 306 within the first trench 312 and a p-MOS cavity 308C in the exposed surface of the p-type semiconductor region 308 within the second trench 314, as shown in FIG. 3B. The cavity shaping process may be performed in an etch chamber, such as the processing chamber 120 shown in FIG. 1. The cavity shaping process in block 220 may be performed without breaking vacuum environment in a multi-chamber processing system, such as the multi-chamber processing system 100 shown in FIG. 1.

The cavity shaping process in block 220 includes an etch process using an etching gas including halogen-containing gas, such as chlorine (Cl₂), hydrogen chloride (HCl), or hydrogen fluoride (HF), and carrier gas, such as include argon (Ar), or helium (He). An etch process using chlorine (Cl₂) and hydrogen (H₂) is sensitive to the amount of germanium (Ge), and thus this cavity shaping process reacts differently on the n-type semiconductor region 306 (e.g., silicon (Si)) and the p-type semiconductor region 308 (e.g., silicon germanium (SiGe)). This difference may cause the difference in deposition rates of metal material on the exposed surface on the n-MOS cavity 306C (e.g., silicon (Si)) and the exposed surface on the p-MOS cavity 308C (e.g., silicon germanium (SiGe)) in the subsequent selective deposition processes.

The n-MOS and p-MOS cavities 306C and 308C may have a V-shape, a U-shape, or any other shape, having a width of between about 5 nm and about 15 nm and a depth of between about 5 nm and about 15 nm, and enlarge a contact area between the p-type semiconductor region 308 and a contact plug to be formed within the second trench 314, to minimize parasitic resistance, leading to an improved device performance.

The cavity shaping process is used to refresh (e.g., etching a surface of about a few nanometers that is potentially contaminated with remaining oxygen, nitrogen, or carbon) and prepare pure contamination free exposed surfaces of the n-MOS and p-MOS cavities 306C and 308C on which a contact (e.g., metal silicide) can be formed selectively within the p-MOS cavity 308C in a subsequent deposition process. The cavity shaping process is also used to optimize a device stress.

In block 230, a first selective deposition process is performed to form a p-MOS cavity contact 316 selectively in the p-MOS cavity 308C, as shown in FIG. 3C. The first selective deposition process may be performed in a processing chamber, such as the processing chamber 126, 128, or 130 shown in FIG. 1. The first selective deposition process in block 230 may be performed without breaking vacuum environment in a multi-chamber processing system, such as the multi-chamber processing system 100 shown in FIG. 1.

The p-MOS cavity contact 316 may be formed of a first metal material, such as molybdenum (Mo), ruthenium (Ru), or silicide thereof. The p-MOS cavity contact 316 interfaces with the p-type semiconductor region 308 and a contact plug to be formed within the second trench 314, and provides an electrical connection therebetween.

In some embodiments, the first selective deposition process includes a deposition process, such as chemical vapor deposition (CVD), physical vapor deposition (PVD), or the like. The selectivity in the first selective deposition process may arise from differences in reactions of a deposition precursor of the first metal material (e.g., molybdenum (Mo), ruthenium (Ru)) with the exposed surface of the n-MOS cavity 306C (e.g., silicon (Si), passivated silicon (Si) surface) and the exposed surface of the p-MOS cavity 308C (e.g., silicon germanium (SiGe)). During the deposition process, the deposition precursor reacts preferentially with the exposed surface of the p-MOS cavity 308C (e.g., silicon germanium (SiGe)) to the exposed surface of the n-MOS cavity 306C (e.g., silicon (Si), passivated silicon (Si) surface), and thus growth of the first metal material may occur at a faster rate on the exposed surface of the p-MOS cavity 308C than the exposed surface of the n-MOS cavity 306C.

In some embodiments, a deposition gas used in the deposition process includes a metal source, such as a molybdenum (Mo)-containing halide precursor, or a ruthenium (Ru)-containing organometallic that includes ruthenium (Ru). The first selective deposition process may be performed at a temperature of between about 240° C. and about 450° C. and at a pressure of between 3 Torr and 300 Torr. During the deposition process, argon (Ar) gas may be supplied at a flow rate of between about 0 sccm and about 1000 sccm, and hydrogen (H₂) gas may be supplied at a flow rate of between about 500 sccm and about 15000 sccm, for example.

A cycle of the first selective deposition process may be repeated as needed to obtain a desired thickness of the p-MOS cavity contact 316, for example, between about 5 times and about 1000 times.

In block 240, a metal treatment process is performed to remove oxides at interfaces of the p-MOS cavity contact 316 (e.g., molybdenum (Mo), ruthenium (Ru), or silicide thereof) with the p-MOS cavity 308C (e.g., SiGe:B). In some embodiments, the metal treatment process removes oxides at interfaces of the n-MOS cavity contact 318 (e.g., as titanium (Ti), cobalt (Co), nickel (Ni), tantalum (Ta), lanthanum (La), yttrium (Y), hafnium (Hf), zirconium (Zr), or silicide thereof) with the n-MOS cavity 306C (e.g., Si:P).

The metal treatment process may include a capacitively coupled plasma (CCP) or an inductively couple plasma (ICP) chemical etch process with ion bombardment using processing gas including hydrogen (H₂) and argon (Ar), performed in a processing chamber, such as Preclean XT chamber available from Applied Materials of Santa Clara, Calif., or the processing chamber 122 shown in FIG. 1. The metal treatment process in block 240 may be performed without breaking vacuum environment in a multi-chamber processing system, such as the multi-chamber processing system 100 shown in FIG. 1. The metal treatment process may be performed under a pressure of about 2 mTorr at an ICP power of about 900 W and a bias power of between 0 W and about 200 W for a time duration of about 90 seconds. During the metal treatment process, argon (Ar) gas may be supplied at a flow rate of about 20 sccm and hydrogen (H₂) gas may be supplied at a flow rate of about 20 sccm.

The inventors have observed a metal treatment on a molybdenum silicide (MoSiₓ) layer formed on a cavity within a SiGe:B region improves structural quality (e.g., reduced defects and impurities) of the molybdenum silicide (MoSiₓ) layer at the interface with the cavity.

While not intending to be bound by theory, during the metal treatment process, hydrogen radicals (H*) diffuse through the molybdenum silicide (MoSiₓ) layer and react with the interface with the cavity (MoSiₓ/SiGe:B interface), and thus remove oxygen at the interface.

In block 250, a second selective deposition process is optionally performed to form an n-MOS cavity contact 318 selectively in the n-MOS cavity 306C, as shown in FIG. 3D. The second selective deposition process may be performed in a processing chamber, such as the processing chamber 126, 128, or 130 shown in FIG. 1. The second selective deposition process in block 250 may be performed without breaking vacuum environment in a multi-chamber processing system, such as the multi-chamber processing system 100 shown in FIG. 1.

The n-MOS cavity contact 318 may be formed of a second metal material, such as titanium (Ti), cobalt (Co), nickel (Ni), tantalum (Ta), lanthanum (La), yttrium (Y), hafnium (Hf), zirconium (Zr), or silicide thereof. The n-MOS cavity contact 318 interfaces with the n-type semiconductor region 306 and a contact plug to be formed within the first trench 312, and provides an electrical connection therebeween.

In some embodiments, the second selective deposition process includes a deposition process, such chemical vapor deposition (CVD), physical vapor deposition (PVD), or the like. The selectivity in the second selective deposition process may arise from differences in reactions of a deposition precursor of the second metal material (e.g., titanium (Ti)) with the exposed surface of the n-MOS cavity 306C (e.g., silicon (Si)) and the exposed surface of the p-MOS cavity contact 316 (e.g., molybdenum (Mo), ruthenium (Ru)). During the deposition process, the deposition precursor reacts preferentially with the exposed surface of the n-MOS cavity 306C (e.g., silicon (Si)) to the exposed surface of the p-MOS cavity contact 316 (e.g., molybdenum (Mo), ruthenium (Ru)), and growth of the second metal material may occur at a faster rate on the exposed surface of the n-MOS cavity 306C than the exposed surface of the p-MOS cavity contact 316 (e.g., molybdenum (Mo), ruthenium (Ru)).

In some embodiments, a deposition gas used in the deposition process includes a metal source, such as a precursor containing titanium (Ti), tantalum (Ta), cobalt (Co), nickel (Ni), combination thereof. The second selective deposition process may be performed at a temperature of between about 300° C. and about 800° C. and at a pressure of between 1° Torr and 50° Torr.

In block 260, a blanket deposition process is performed to form a barrier metal layer 320 on the exposed inner surfaces of the first trench 312 and the second trench 314, and the exposed surface of the dielectric layer 310, as shown in FIG. 3E. The barrier metal layer 320 protects the p-MOS cavity contact 316 and the n-MOS cavity contact 318 and allows nucleation and growth of contact plugs in the first trench 312 and the second trench 314. The barrier metal layer 320 may be formed of a barrier metal material that is titanium nitride (TiN), or tantalum nitride (TaN). In some embodiments, the n-MOS cavity contact 318 is a silicide layer that is formed from a portion of the barrier metal layer 320 by use of a spike anneal process. The blanket deposition process in block 260 may be performed without breaking vacuum environment in a multi-chamber processing system, such as the multi-chamber processing system 100 shown in FIG. 1.

In block 270, a metal fill process is performed to form a first contact plug 322 in the first trench 312 and a second contact plug 324 in the second trench 314, as shown in FIG. 3F. The first contact plug 322 and the second contact plug 324 may be formed of contact plug metal material, such as tungsten (W), cobalt (Co), ruthenium (Ru), or molybdenum (Mo). The first contact plug 322 and the second contact plug 324 may include a metal that has a desirable work function. The metal fill process in block 270 may include a chemical vapor deposition (CVD) process using a tungsten-containing precursor, such as WF₆, or a cobalt-containing precursor, in a processing chamber, such as the processing chamber 126, 128, or 130 shown in FIG. 1.

After the metal fill process, the semiconductor structure 300 may be planarized, by use of a chemical mechanical planarization (CMP) process.

The embodiments described herein provide methods and system for forming an electrical contact that includes metal silicide (e.g. molybdenum silicide (MoSi₂), ruthenium silicide (RuₓSi_{y})) within a trench on a selected portion of a transistor structure, and further improving structural and electrical qualities of the metal silicide at the interface with the trench. The contact trench structure includes a metal contact plug formed within a trench between adjacent device modules, and electrical contacts that interface between the contact plug and silicon-based channels in the device modules, reducing parasitic resistance. The electrical contacts are formed by a selective deposition and oxides in the electrical contacts are removed by a CCP chemical etch process with ion bombardment using processing gas including hydrogen (H₂) and argon (Ar). The electrical contact may be of metal silicide (e.g. molybdenum silicide (MoSi₂), ruthenium silicide (RuₓSi_{y})) selectively formed in a trench in a p-type MOS device (e.g., silicon germanium), or of metal silicide (e.g., titanium silicide (Ti Si₂)) selectively formed in a trench in an n-type MOS device.

While the foregoing is directed to embodiments of the present disclosure, other and further embodiments of the disclosure may be devised without departing from the basic scope thereof, and the scope thereof is determined by the claims that follow.

1. A method of forming an electrical contact in a semiconductor structure, comprising:
performing a cavity shaping process on a semiconductor structure having a p-type semiconductor region for a p-type metal oxide semiconductor (p-MOS) device, the cavity shaping process comprising forming a first cavity in an exposed surface of the p-type semiconductor region;
performing a first selective deposition process to form a first cavity contact, selectively in the first cavity; and
performing a metal treatment process on the formed first cavity contact, to remove oxides at interfaces of the first cavity contact with the first cavity.

2. The method of claim 1, wherein the metal treatment process includes a capacitively coupled plasma (CCP) chemical etch process with ion bombardment using processing gas including hydrogen (H₂) and argon (Ar).

3. The method of claim 1, wherein:
the first cavity contact comprises material selected from molybdenum (Mo) silicide and ruthenium (Ru) silicide.

4. The method of claim 1, wherein:
the semiconductor structure further includes an n-type semiconductor region for an n-type metal oxide semiconductor (n-MOS) device, and
the cavity shaping process further comprises forming a second cavity in an exposed surface of the n-type semiconductor region.

5. The method of claim 4, wherein:
the n-type semiconductor region comprises silicon doped with n-type dopants, and
the p-type semiconductor region comprises silicon germanium doped with p-type dopants, wherein
the cavity shaping process comprises:
an etch process using chlorine (Cl₂) and hydrogen (H₂).

6. The method of claim 4, further comprising:
subsequent to the metal treatment process, performing a second selective deposition process to form a second cavity contact, selectively in the second cavity,
wherein the second cavity contact comprises titanium (Ti) silicide.

7. The method of claim 4, further comprising:
prior to the cavity shaping process, performing a pre-clean process, comprising:
removing carbon-containing contaminants from the exposed surfaces of the n-type semiconductor region and the p-type semiconductor region, by a dry etch process using hydrogen (H) plasma; and
removing oxide-containing contaminants from the exposed surfaces of the n-type semiconductor region and the p-type semiconductor region, by a dry etch process.

8. The method of claim 1, wherein
the cavity shaping process, the first selective deposition process, and the metal treatment process are performed without breaking vacuum environment.

9. A method of forming an electrical contact in a semiconductor structure, comprising:
performing a pre-clean process on a semiconductor structure having an n-type semiconductor region for an n-type metal oxide semiconductor (n-MOS) device, and a p-type semiconductor region for a p-type metal oxide semiconductor (p-MOS) device, and a dielectric layer having a first trench over the n-type semiconductor region and a second trench over the p-type semiconductor region;
performing a cavity shaping process to form a second cavity in an exposed surface of the n-type semiconductor region within the first trench and a first cavity in an exposed surface of the p-type semiconductor region within the second trench;
performing a first selective deposition process to form a first cavity contact, selectively in the first cavity;
performing a metal treatment process on the formed first cavity contact, to remove oxides at interfaces of the first cavity contact with the first cavity;
performing a second selective deposition process to form a second cavity contact, selectively in the second cavity;
performing a blanket deposition process to form a barrier layer on exposed inner surfaces of the first trench and the second trench and on the exposed surface of the dielectric layer; and
performing a metal fill process to form a first contact plug in the first trench and a second contact plug in the second trench.

10. The method of claim 9, wherein the pre-clean process, the cavity shaping process, the first selective deposition process, the metal treatment process, the second selective deposition process, and the blanket deposition process are performed without breaking vacuum environment.

11. The method of claim 9, wherein the metal treatment process includes a capacitively coupled plasma (CCP) chemical etch process with ion bombardment using processing gas including hydrogen (H₂) and argon (Ar).

12. The method of claim 9, wherein
the n-type semiconductor region comprises silicon doped with n-type dopants, and
the p-type semiconductor region comprises silicon germanium doped with p-type dopants, wherein
the cavity shaping process comprises:
an etch process using chlorine (Cl₂) and hydrogen (H₂).

13. The method of claim 9, wherein
the first cavity contact comprises material selected from molybdenum (Mo) silicide and ruthenium (Ru) silicide, and
the second cavity contact comprises titanium (Ti) silicide.

14. The method of claim 9, wherein the pre-clean process comprises:
removing carbon-containing contaminants from the exposed surfaces of the n-type semiconductor region and the p-type semiconductor region, by a dry etch process using hydrogen (H) plasma; and
removing oxide-containing contaminants from the exposed surfaces of the n-type semiconductor region and the p-type semiconductor region, by a dry etch process.

15. The method of claim 9, wherein the barrier layer comprises titanium nitride (TiN), or tantalum nitride (TaN).

16. The method of claim 9, the first contact plug and the second contact plug comprise tungsten (W).

17. A processing system, comprising:
a first processing chamber;
a second processing chamber;
a third processing chamber; and
a system controller configured to cause the processing system to:
perform, in the first processing chamber, a cavity shaping process on a semiconductor structure having an n-type semiconductor region for an n-type metal oxide semiconductor (n-MOS) device and a p-type semiconductor region for a p-type metal oxide semiconductor (p-MOS) device, the cavity shaping process comprising forming a second cavity in an exposed surface of the n-type semiconductor region and a first cavity in an exposed surface of the p-type semiconductor region;
perform, in the second processing chamber, a first selective deposition process to form a first cavity contact, selectively in the first cavity; and
perform, in the third processing chamber, a metal treatment process on the formed first cavity contact, to remove oxides at interfaces of the first cavity contact with the first cavity, wherein the metal treatment process includes a capacitively coupled plasma (CCP) chemical etch process with ion bombardment using processing gas including hydrogen (H₂) and argon (Ar).

18. The processing system of claim 17, further comprising:
a fourth processing chamber, wherein the system controller is further configured to:
prior to the cavity shaping process, perform, in the fourth processing chamber, a pre-clean process, comprising:
removing carbon-containing contaminants from the exposed surfaces of the n-type semiconductor region and the p-type semiconductor region, by a dry etch process using hydrogen (H) plasma; and
removing oxide-containing contaminants from the exposed surfaces of the n-type semiconductor region and the p-type semiconductor region, by a dry etch process.

19. The processing system of claim 17, further comprising:
a fifth processing chamber, wherein the system controller is further configured to:
subsequent to the metal treatment process, perform, in the fifth processing chamber, a second selective deposition process to form a second cavity contact, selectively in the second cavity.

20. The processing system of claim 17, wherein the system controller is further configured to cause the processing system to perform the cavity shaping process, the first selective deposition process, and the metal treatment process without breaking vacuum environment.
